(19) United States
(12) Patent Application Publication
(10) Pub. No.: US 2024/0186966 A1
(43) Pub. Date: Jun. 6, 2024

(54) RADIO FREQUENCY PUSHPULL POWER AMPLIFIER

(71) Applicant: Spreadtrum Communications USA Inc., San Jose, CA (US)

(72) Inventors: Jason X Deng, Greensboro (NC); Rattapon Lertpiriyapong, Colfax, NC (US)

(21) Appl. No.: 18/073,658

(22) Filed: Dec. 2, 2022

(51) Int. Cl. H03F 3/26; H03F 1/02; H03F 1/56

(52) U.S. Cl. CPC H03F 3/26; H03F 1/0216; H03F 1/565; H03F 2200/318; H03F 2200/451; H03F 2200/541; H03F 2200/546

(57) ABSTRACT

Radio-frequency amplifier circuit including: a first matching circuit; a driver stage circuit, in which the first matching circuit is coupled to the driver stage circuit, and in which the first matching circuit is configured to transform an input impedance of the driver stage circuit into a first impedance at an input to the first matching circuit; an inter-stage matching circuit coupled to the driver stage circuit; an output stage circuit coupled to the inter-stage matching circuit, in which the inter-stage matching circuit is configured to transform an input impedance of the output stage circuit into a second impedance at an output of the driver stage circuit; and and a second matching circuit coupled to the output stage circuit, in which the second matching circuit is configured to transform an impedance at an output of the second matching circuit into a third impedance at the output of the output stage circuit.

### BACKGROUND

Radio frequency (RF) power amplifiers are used in modern digital telecommunications to amplify RF signals, e.g., for transmission to base stations and other devices. In a wireless terminal, such as a cellular phone, a RF power amplifier front end module amplifies a modulated RF signal from a transceiver baseband and sends the signal to an antenna for radiating out to a base station. To maintain high performance, RF power amplifiers are designed to reduce battery consumption and spurious emissions, while still achieving the required output power. Performance may be evaluated based on certain parameters, such as output power, gain, power added efficiency (PAE), linearity (e.g., adjacent cannel power ratio or error vector magnitude), and harmonics leakage, among other factors. The RF power amplifier performance may determine what mode (2G, 3G, 4G, 5G, and WiFi) the transceiver can support, how long the battery can last, and how stable the communication link is.

### SUMMARY

In general, in some aspects, the subject matter of the present disclosure can be embodied in a radio-frequency (RF) push-pull amplifier circuit, in which the RF amplifier circuit includes: a first matching circuit; a driver stage circuit, in which the first matching circuit is coupled to the driver stage circuit, and in which the first matching circuit is configured to transform an input impedance of the driver stage circuit into a first impedance at an input to the first matching circuit; an inter-stage matching circuit coupled to the driver stage circuit; an output stage circuit coupled to the inter-stage matching circuit, in which in the inter-stage matching circuit is configured to transform an input impedance of the output stage circuit into a second impedance at an output of the driver stage circuit; and a second matching circuit coupled to the output stage circuit, in which the second matching circuit is configured to transform an impedance at an output of the second matching circuit into a third impedance at the output of the output stage circuit.

Implementations of the circuit can include one or more of the following features. For example, in some implementations, the first matching circuit includes a first transformer, in which the first transformer is arranged to split an input signal to the first transformer into a first transformed signal and a second transformed signal that is out of phase with the first transformed signal.

In some implementations, the driver stage circuit includes a first driver stage amplifier and a second driver stage amplifier, in which the first driver stage amplifier is arranged to receive the first transformed signal and the second driver stage amplifier is arranged to receive the second transformed signal. The inter-stage matching circuit can include: a first matching circuit coupled to an output of the first driver stage amplifier; and a second matching circuit coupled to an output of the second driver stage amplifier. The first matching circuit can include a first inductor-capacitor (LC) matching circuit, and the second matching circuit can include a second LC matching circuit. The first LC matching circuit can include a first capacitor coupled to an output of the first driver stage amplifier, and the second LC matching circuit can include a second capacitor coupled to an output of the second driver stage amplifier. The first LC matching circuit can include a first inductor coupled between the first capacitor and ground, and the second LC matching circuit can include a second inductor coupled between the second capacitor and ground. The first LC matching circuit can include a third inductor coupled between the first capacitor and a voltage source, and the second LC matching circuit can include a fourth inductor coupled between the second capacitor and the voltage source. The first LC matching circuit can include a third capacitor coupled to the first capacitor and to the first inductor, and the second LC matching circuit can include a fourth capacitor coupled to the second capacitor and to the second inductor. Each of the first inductor and the second inductor can be an adjustable inductor, and each of the first capacitor and the second capacitor can be an adjustable capacitor. An impedance at the output of the first driver stage amplifier and at an input to the first LC matching circuit can be between about 10 ohms and about 150 ohms, and an impedance at the output of the second driver stage amplifier and at an input to the second LC matching circuit can be between about 10 ohms and about 150 ohms. An impedance at an output of the first LC matching circuit can be between about 0.1 ohms and about 1 ohm, and an impedance at an output of the second LC matching circuit can be between about 0.1 ohms and about 1 ohms

In some implementations, the impedance at the output of the second matching circuit is 50 ohms

In general, in some other aspects, the subject matter of the present disclosure can be embodied in a radio-frequency (RF)-circuit that includes: a processor; modulation circuitry coupled to an output of the processor; a push-pull amplifier circuit coupled to an output of the modulation circuitry; and an antenna, in which the push-pull amplifier circuit includes a first matching circuit, a driver stage circuit, in which the first matching circuit is coupled to the driver stage circuit, and in which the first matching circuit is configured to transform an input impedance of the driver stage circuit into a first impedance at an input to the first matching circuit. The push-pull amplifier circuit can further include an inter-stage matching circuit coupled to the driver stage circuit, an output stage circuit coupled to the inter-stage matching circuit, in which the inter-stage matching circuit is configured to transform an input impedance of the output stage circuit into a second impedance at an output of the driver stage circuit, and a second matching circuit coupled to the output stage circuit, in which the second matching circuit is configured to transform an impedance at an output of the second matching circuit into a third impedance at the output of the output stage circuit.

Implementations of the circuit can include one or more of the following features. For example, in some implementations, the first matching circuit can include a first transformer, in which the first transformer is arranged to split an input signal to the first transformer into a first transformed signal and a second transformed signal that is out of phase with the first transformed signal. The driver stage circuit can include a first driver stage amplifier and a second driver stage amplifier, in which the first driver stage amplifier is arranged to receive the first transformed signal and the second driver stage amplifier is arranged to receive the second transformed signal. The inter-stage matching circuit can include: a first matching circuit coupled to an output of the first driver stage amplifier; and a second matching circuit coupled to an output of the second driver stage amplifier. The first matching circuit can include a first inductor-capacitor (LC) matching circuit, and the second matching circuit can include a second LC matching circuit.

In general, in some other aspects, the subject matter of the present disclosure can be embodied in a method of tuning an impedance of a radio-frequency (RF) push-pull amplifier circuit including a first matching circuit, a driver stage circuit coupled to an output of the first matching circuit, an inter-stage matching circuit coupled to an output of the driver circuit, an output stage circuit coupled to an output of the inter-stage matching circuit, and a second matching circuit coupled to an output of output stage circuit, in which the method includes: obtaining an impedance at the input of the output stage circuit; adjusting an impedance matching of the inter-stage matching circuit so as to obtain a predefined impedance at the output of driver stage circuit.

Implementations of the method can include one or more of the following features. For example, in some implementations, adjusting the impedance matching of the inter-stage matching circuit can include: adjusting an inductance of a first adjustable inductor of the inter-stage matching circuit; and adjusting a capacitance of a first adjustable capacitor of the inter-stage matching circuit.

The subject matter described in this specification can be implemented in particular embodiments or implementations to realize one or more of the following advantages. For example, in some implementations, the RF front end circuitry of the present disclosure, and specifically, for push pull topologies in certain implementations, can help to reduce the amount of space used by the circuitry and to reduce guesswork and time involved in circuit design. In particular, in the RF amplifier front end circuitry of the present disclosure, the component that splits the incoming signal, e.g., the primary transformer, is placed upstream of one or more of the driver stages of the amplifier, rather than downstream of the one or more driver stages. By placing the transformer upstream of the driver stage(s), the power at the upstream end of the driver stage typically is smaller than at the downstream end of the driver stage, which means that less current passes through the transformer. With less current being handled by the transformer, the transformer traces/leads then can be designed to have a smaller overall size, which can reduce the amount of chip space being used and/or improve the efficient utilization of available chip area. Moreover, since the transformer is placed upstream of the driver stage(s), the required impedance transformation to be provided by the transformer may be reduced, which in turn means a smaller transformer design can be used, resulting in more efficient use of and/or additional reduction in chip space.

The details of one or more embodiments of the subject matter of this specification are set forth in the accompanying drawings and the description below. Other features, aspects, and advantages of the subject matter will become apparent from the description, the drawings, and the claims.

### BRIEF DESCRIPTION OF THE DRAWINGS

FIG. 1 is a schematic diagram of an example of a wireless communication system.

FIG. 2 is a block diagram of example details of a wireless device.

FIG. 3A is a schematic diagram that illustrates an example of RF front end circuitry.

FIG. 3B is a schematic diagram that illustrates an example of RF front end circuitry.

FIG. 4A is a schematic diagram that illustrates an example of RF front end circuitry.

FIG. 4B is a schematic diagram that illustrates an example of RF front end circuitry.

### DETAILED DESCRIPTION

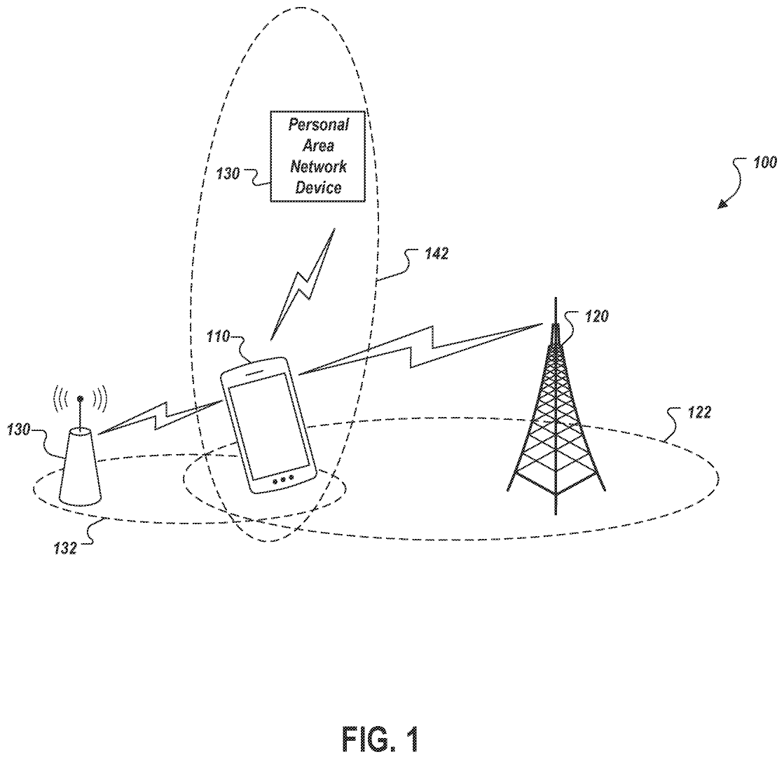

FIG. 1 is a schematic diagram of an example wireless communication system 100 including a wireless device 110 capable of communicating with one or more wireless communication networks. The one or more wireless communication networks with which the wireless device 110 is capable of communicating can include but is not limited to one or more cellular or wireless wide area networks (WWANs), one or more wireless local area networks (WLANs), one or more wireless personal area networks (WPANs), or a combination thereof.

In the example of FIG. 1, the wireless device 110 is communicating with at least one WWAN by way of at least one base station 120 and at least one WLAN by way of at least one access point 130. The at least one base station 120 can support bi-directional communication with wireless devices that are within its corresponding area of coverage 122. Similarly, the at least one access point 130 can support bi-directional communication with wireless devices that are within its corresponding area of coverage 132.

In some implementations, the at least one WWAN with which the at least one base station 120 is associated can be a fifth generation (5G) network among other generations and types of networks. In these implementations, the at least one base station 120 can be a 5G base station that employs orthogonal frequency-division multiplexing (OFDM) and/or non-OFDM and a transmission time interval (TTI) shorter than 1 ms (e.g. 100 or 200 microseconds), to communicate with wireless devices, such as wireless device 110. For example, the at least one base station 120 can take the form of one of several devices, such as a base transceiver station (BTS), a Node-B (NodeB), an evolved NodeB (eNB), a next (fifth) generation (5G) NodeB (gNB), a Home NodeB, a Home eNodeB, a site controller, an access point, a wireless router, a server, router, switch, or other processing entity with a wired or wireless network.

System 100 can use multiple channel access functionality, including for example schemes in which the at least one base station 120 and the wireless device 110 are configured to implement the Long Term Evolution wireless communication standard (LTE), LTE Advanced (LTE-A), and/or LTE Multimedia Broadcast Multicast Service (MBMS). In other implementations, the at least one base stations 120 and wireless device 110 are configured to implement UMTS, HSPA, or HSPA+ standards and protocols. Of course, other multiple access schemes and wireless protocols can be utilized. In some examples, one or more such access schemes and wireless protocols can correspond to standards that impose RF power amplifier linearity requirements.

In addition, and as shown in FIG. 1, wireless device 110 is configured to communicate with one or more personal area network (PAN) devices/systems 130 (e.g., Bluetooth® or radio frequency identification (RFID) systems and devices) over one or more WPANs. The one or more PAN devices/systems 130 can support either one-way or bi-directional communication with wireless devices that are within its corresponding area of coverage 142.

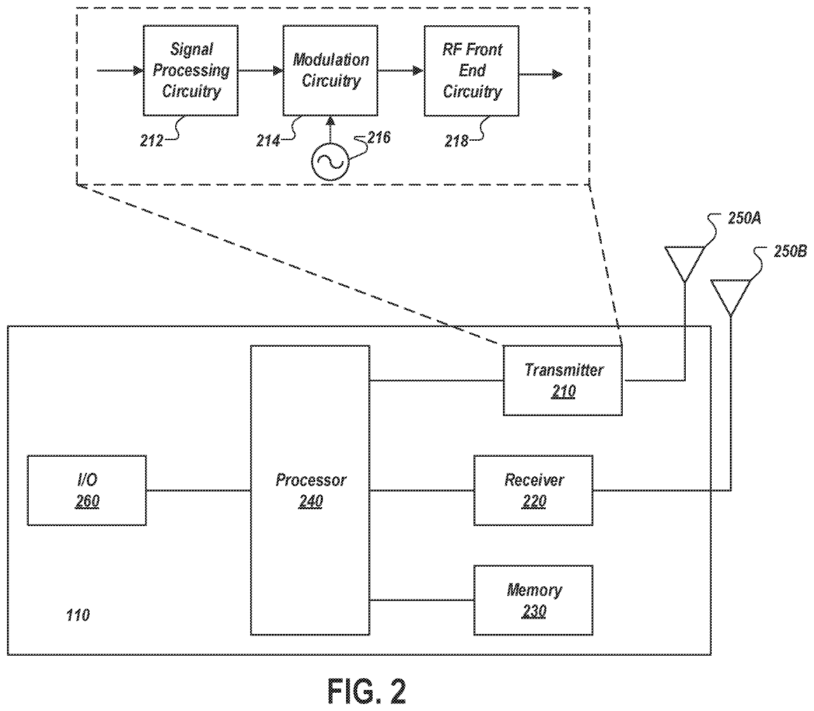

To communicate with one or both of the at least one base station 120 and the access point 130, the wireless device 110 can include singular or multiple transmitter and receiver components similar or equivalent to one or more of those described in further detail below with reference to FIG. 2 to support multiple communications with different types of access points, base stations, and other wireless communication devices.

Although FIG. 1 illustrates one example of a communication system, various changes can be made to FIG. 1. For example, the communication system 100 could include any number of wireless devices, base stations, access points, networks, or other components in any suitable configuration.

FIG. 2 is a block diagram that illustrates example details of the wireless device 110 that can implement the subject matter according to this disclosure. The wireless device 110 can, for example, be a mobile telephone, but can be other devices in further examples such as a desktop computer, laptop computer, tablet, hand-held computing device, drone, automobile computing device and/or other computing devices. As shown in the figure, the wireless device 110 is shown as including at least one transmitter 210, at least one receiver 220, memory 230, at least one processor 240, and at least one input/output device 260. Here, only one transmitter and only one receiver are shown, but in many embodiments, multiple transmitters and receivers are included to support multiple communications of different types at the same time. Each transmitter may employ the innovations of the present disclosure.

The processor 240 can implement various processing operations of the wireless device 110. For example, the processor 240 can perform signal generation, signal coding, signal analysis, data processing, power control, input/output processing, or any other functionality enabling the wireless device 110 to operate in a communication system, such as system 100 (FIG. 1). The processor 240 can include any suitable processing or computing device configured to perform one or more operations. For example, the processor 240 can include a microprocessor, microcontroller, digital signal processor, field programmable gate array, or application specific integrated circuit, or a combination of these devices.

The transmitter 210 can be configured to modulate data or other content, filter and amplify outgoing radio frequency (RF) signals for transmission by at least one antenna 250A. In some implementations, the transmitter 210 can also be configured to amplify, filter and upconvert baseband or intermediate frequency signals to radio frequency (RF) signals before such signals are provided to the antenna 250A for transmission. The transmitter 210 can include any suitable structure for generating RF signals for wireless transmission. Additional aspects of the transmitter 210 are described in further detail below with reference to components 212-218 as depicted in FIG. 2.

The receiver 220 can be configured to demodulate data or other content received in incoming RF signals by at least one antenna 250B. In some implementations, the receiver 220 can also be configured to amplify, filter and frequency down convert RF signals received via the antenna 250B either to intermediate frequency (IF) or baseband frequency signals prior to conversion to digital form and processing. The receiver 220 can include any suitable structure for processing signals received wirelessly.

Each of the antennas 250A and 250B can include any suitable structure for transmitting and/or receiving wireless RF signals. In some implementations, the antennas 250A and 250B can be implemented by way of a single antenna that can be used for both transmitting and receiving RF signals.

One or multiple transmitters 210, one or multiple receivers 220, and one or multiple antennas 250 could be used in the wireless device 110. For example, in one embodiment, device 110 includes at least three transmitters 210 and at least three receivers 220 for communicating via at least a personal area network such as Bluetooth®, a WiFi network such as an IEEE 802.11 based network, and a cellular network, respectively. Each transmitter 210 may employ the concepts of the present disclosure. Although shown as separate blocks or components, at least one transmitter 210 and at least one receiver 220 could be combined into a transceiver Each transceiver may employ the concepts of the present disclosure. Accordingly, rather than showing a separate block for the transmitter 210 and a separate block for the receiver 220 in FIG. 2, a single block for a transceiver could have been shown.

The wireless device 110 further includes one or more input/output (I/O) devices 260. The I/O devices 260 facilitate interaction with a user. Each I/O device 260 includes any suitable structure for providing information to or receiving information from a user, such as a speaker, microphone, keypad, keyboard, display, and/or touch screen.

In addition, the wireless device 110 includes at least one memory 230. The memory 230 stores instructions and data used, generated, and/or collected by the wireless device 110. For example, the memory 230 could store software or firmware instructions executed by the processor(s) 240 and data used to reduce or eliminate interference in incoming signals. Each memory 230 includes any suitable volatile and/or non-volatile storage and retrieval device(s). Any suitable type of memory may be used, such as random access memory (RAM), read only memory (ROM), solid state drive, hard disk drive, optical disc, subscriber identity module (SIM) card, memory stick, secure digital (SD) memory card, and the like.

In some implementations, the transmitter 210 can include signal processing circuitry 212, modulation circuitry 214, and RF front end circuitry 218. The signal processing circuitry 212 may include one or more circuits that are configured to process signals received as input (e.g. from processor 240). For example, the signal processing circuitry 212 may include a digital-to-analog converter (D/A), which converts a digital input (e.g. a digital signal from processor 240) into an analog signal, which is then provided to a low pass filter, which filters the analog signal and provides the filtered analog signal to the modulation circuitry 214. The modulation circuitry 214, in addition to receiving the filtered analog signal from the signal processing circuitry 212, can, in some implementations, also receive a signal from a local oscillator 216 for modulating or adjusting the frequency of the analog signal, e.g., from a first frequency to a second frequency that is higher than the first frequency. For instance, the modulation circuitry 214 can include a mixer that frequency up-converts the filtered analog signal from a relatively low frequency (e.g. baseband frequency, or an intermediate frequency (IF) that is offset from the baseband frequency) to a relatively high frequency RF signal. Thus, a signal from the local oscillator 216 is used as a carrier signal in transmitter 210. Moreover, as shown in FIG. 2, transmitter 210 includes RF front end circuitry 218, which can include, e.g., amplification and filtering circuits that amplify and filter, respectively, the RF signal. The RF front end circuitry can also include one or more power amplifiers configured to provide sufficient amplification of the signal to meet transmission requirements, as may be specified by wireless communication standards. Examples of such standards include those set forth by the 3rd Generation Partnership Project (3GPP), which is a group that unites seven telecommunications standard development organizations (ARIB, ATIS, CCSA, ETSI, TSDSI, TTA, TTC) and that develops standards for cellular telecommunications technologies, including radio access, core network and service capabilities, which provide a complete system description for mobile telecommunications.

The RF signal amplified by the one or more power amplifiers may be filtered again by at least one additional filter downstream of the one or more power amplifiers before being provided as an output of the transmitter 210 to the at least one antenna 250A for wireless transmission. Such filter or filters can alternatively, or additionally, be provided upstream from the one or more power amplifiers in which case the output of the power amplifier is provided to the at least one antenna 250A for wireless transmission. The RF front end circuitry usually includes multiple amplifier stages, in which the output stage is the final amplifier stage of the RF front end circuitry. The other amplifier stages are typically called driver stages.

For various wireless communication standards, there are strict requirements as to amplifier linearity so that signals can be faithfully amplified prior to transmission. However, increasing linearity often leads to a sacrifice in efficiency (measured, e.g., through PAE), given that higher power levels tend to result in substantial power dissipation through heat loss. Moreover, power supply design limitations often restrict the amount of power RF front end circuitry consumes during operation. To improve efficiency, such as PAE, for RF front end circuitry, one option is to increase the gain of the output stage as much as possible so that the number of amplification stages is reduced (e.g., from three amplifier stages to two amplifier stages).

An additional technique for improving gain and efficiency requirements of certain wireless transmission protocols is to employ push pull amplifiers in the RF front end circuitry. A push pull amplifier is an amplifier in which an incoming signal is split, usually by a primary transformer, across two separate arms, where the signal on one arm is 180 degrees out of phase with the signal on the other arm. In a simplified example, the push pull amplifier uses two bipolar junction transistors or two MOSFETs, one for each arm, where one of the transistors sources current through the load, while the other transistor sinks current from the load. After a defined period of time, the transistors switch functionality such that the transistor originally sourcing current through the load instead sinks current from the load, and the other transistor originally sinking current from the load begins to source current through the load. This process is repeated during operation of the push pull amplifier. Following amplification by the transistors, the separate arms are recombined, e.g., by a secondary transformer, before being provided to an output, such as the antenna of the transceiver. The push-pull amplifier thus uses neutralization techniques to cancel undesirable device parasitic capacitances, allowing for a significant gain improvement in the output stage, which in turn improves efficiency, without reducing linearity.

RF front end circuitry can utilize on-chip transformers between the driver stage(s) and the output stage for power splitting, phase inversion and inter-stage load matching. In certain implementations, such a topology requires significant die area. This is because, in some implementations, the transformer is designed to include wider traces so as to handle substantial power levels in the signals provided at the output of driver stage(s). Moreover, this topology can make lab tuning the circuit design for inter-stage matching extremely difficult. While computer aided design (CAD) software can be used to provide a general model of the RF front end circuitry, the operating conditions (such as device temperatures reaching more than 120 degrees Celsius and current consumption being over a half ampere), pose significant challenges for CAD simulation tools, such that prediction of actual RF front end circuitry performance based on nonlinear models with such software is quite difficult and inaccurate. Owing to the lack of simulation accuracy, design of RF front end circuitry typically requires a substantial amount of time in the lab testing different versions of the circuit design. For instance, design of RF front end circuitry can require weeks or months in the lab through multiple iterations of designing, fabricating, and testing different circuit designs to see which designs achieve the best improvement in amplifier performance. Such redesign can include changing the shape of the transformers used in the circuit and/or modifying the design of the printed circuit board on which the components are formed, among other modifications. Moreover, for push pull topologies, the circuit performance can be very sensitive to variation in lead inductance associated with the leads of the transformers used in the circuit, which is another factor that complicates designing the RF front circuitry. In some implementations, a transformer includes multiple leads (e.g., 2, 4, 6, 8 or other numbers of leads) coupled in parallel at both ends of the coil, where each of the leads is combined together to form a reduced equivalent lead inductance and resistive loss, further complicating the design.

The present disclosure is directed to a solution for designing RF front end circuitry, and specifically for push pull topologies, that can help, in certain implementations, to reduce the amount of space used by the circuitry and to reduce guesswork and time involved in circuit design. In particular, the present disclosure is directed to RF amplifier front end circuitry in which the component that splits the incoming signal, e.g., the primary transformer, is placed upstream of one or more of the driver stages of the amplifier, rather than downstream of the one or more driver stages. By placing the transformer upstream of the driver stage(s), the power at the upstream end of the driver stage typically is smaller than at the downstream end of the driver stage, which means that less current passes through the transformer. With less current being handled by the transformer, the transformer traces/leads then can be designed to have a smaller overall size, which can reduce the amount of chip space being used and/or improve the efficient utilization of available chip area. Moreover, since the transformer is placed upstream of the driver stage(s), the required impedance transformation to be provided by the transformer may be reduced, which in turn means a smaller transformer design can be used, resulting in more efficient use of and/or additional reduction in chip space.

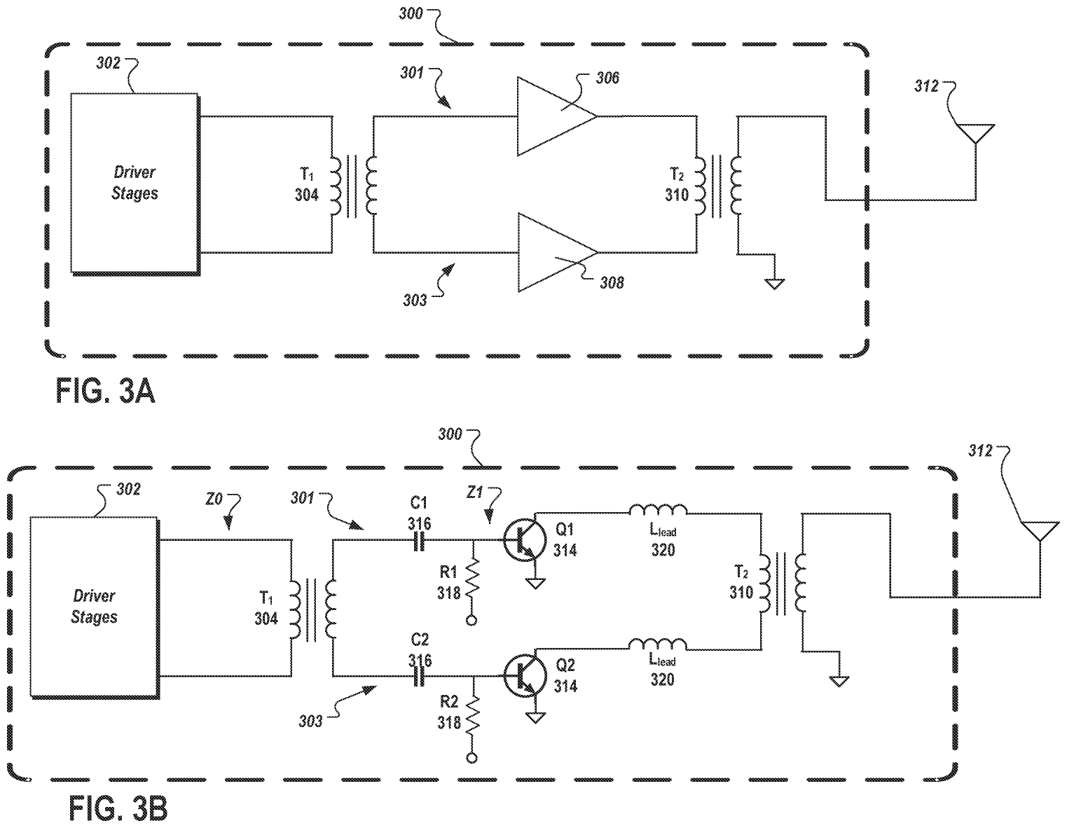

FIG. 3A is a schematic diagram that illustrates an example of RF front end circuitry 300, such as the circuitry 218 shown in FIG. 2. The RF front end circuitry 300 includes a signal splitting component 304 (e.g., a first transformer) that takes an input signal from one or more driver stages 302 of a transmitter (e.g., transmitter 210) and splits the input signal across two arms 301, 303, such that the signal on the first arm 301 is 180 degrees out of phase with the signal on the second arm 303. The first arm 301 includes: a first amplifier 306, whereas the second arm 303 includes a second amplifier 308. The amplified signals from each of amplifier 306 and amplifier 308 are provided to a second transformer 310, which combines the received signals into an output signal. The output signal then is provided to a component such as an antenna 312.

FIG. 3B is a more detailed example of the circuitry 300 shown in FIG. 3A. As shown in FIG. 3B, each of the amplifiers 306, 308 can be implemented using a corresponding transistor 314 (transistor Q1 for amplifier 306 and transistor Q2 for amplifier 308). The transistors 314 in each arm serve to amplify the signal in their respective arms of the RF front end circuitry. The outputs of transistors 314 are each coupled to the secondary transformer 310. The leads (the metal trace connections) of the secondary transformer 310 that are connected to the outputs of the transistors 314 contribute lead inductance 320 to each arm 301, 303. While the transistors 314 are depicted as bipolar junction transistors, other transistors, such as MOSFETs may be used instead, with appropriate modification of the circuit design to accommodate the different operation of MOSFETs compared to bipolar junction transistors. Furthermore, each arm 301, 303 can include a corresponding one or more capacitors 316 (e.g., capacitor C1 for arm 301 and capacitor C2 for arm 303) and one or more resistors 318 (e.g., resistor R1 for arm 301 and resistor R2 for arm 303). Each capacitor 318 is coupled at one end to the output of the transformer 304 and at the other end to an input of the transistor 314 for its respective arm. Similarly, in each arm, the resistor 318 is coupled at one end between the capacitor 316 and the transistor 314 and at the other end to de bias circuitry. Capacitors 316 are called “segmented capacitors” and work together with resistors 318, also referred to as “ballasting” resistors, to provide ballasting for a large output stage device array as well as to provide partial impedance transformation. The bias circuitry to which resistors 318 are tied provides a DC bias for the amplification stage. The transformer 304 together with the capacitors 316 serve as the inter-stage matching circuit to transform a first impedance, Z1, at the input of the transistors 314 to a second impedance, Z0, at the input to transformer 304. While FIGS. 3A-3B depict a particular commonly used push pull topology, other push pull topologies are also possible.

As explained above, because the primary transformer 304 is arranged after the driver stage 302, the transformer needs to be designed to handle higher current levels. Configuring the transformer to handle higher current loads includes, e.g., using wide lead traces, which accordingly takes up more space on the circuit board. Furthermore, the impedance at the output of the driver stage 302, and thus seen as input to the transformer, is fairly high, requiring a substantially large impedance transformation to achieve load matching. To accommodate the large impedance transformation, the transformer 304 is typically designed to employ a large number of turns, usually requiring more chip space.

To reduce the chip space required to accommodate the primary transformer 304, the transformer 304 can be moved upstream of the one or more driver stages 302. By placing the transformer 304 upstream of the driver stage(s), the transformer is required to handle less current and thus can be designed to have smaller trace widths. Furthermore, load matching requires a smaller impedance transformation when the transformer is located before the driver stages. Accordingly, the transformer can be designed with fewer turns and thus take up less chip space.

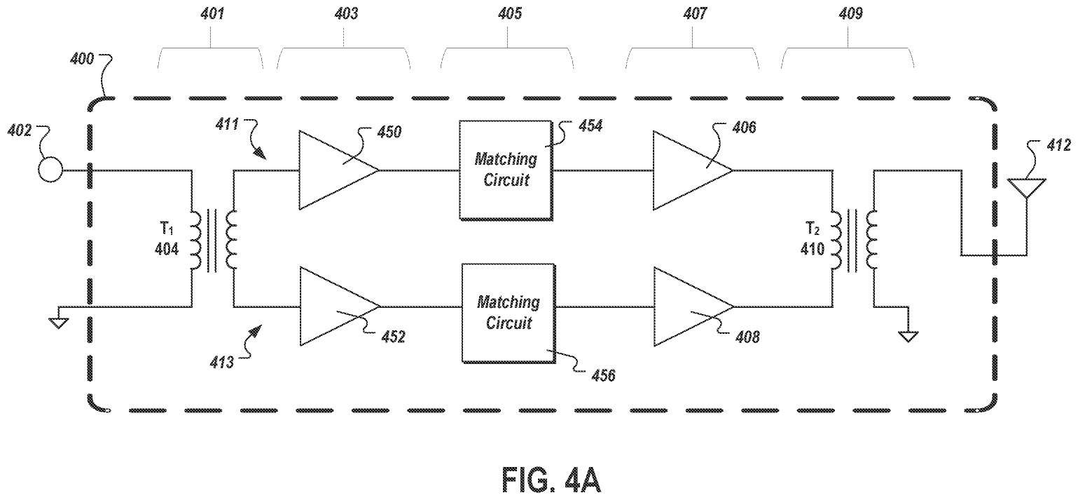

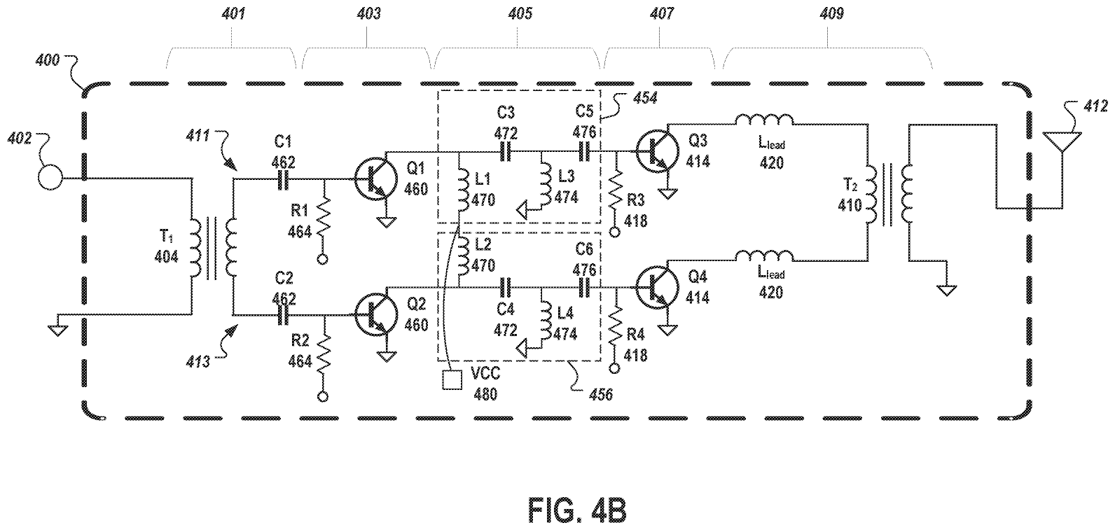

FIG. 4A is a schematic diagram that illustrates an example of RF front end circuitry, such as circuitry 218 shown in FIG. 2, in which the primary transformer used for power splitting and phase inversion in a push-pull topology is located upstream of one or more driver stages instead of downstream of the driver stages. As shown in the example of FIG. 4A, a driver stage is one of several stages within the RF front end circuitry 400. These stages include: an input matching network 401, the driver stage 403 (also referred to as a driver circuit), an inter-stage matching network 405 (also referred to as inter-stage (IS) matching circuit), an output stage 407, and an output matching network 409.

The input matching network 401 transforms the impedance seen at the input of the driver stage 403 to a desired termination impedance at node 402. For instance, the input matching network 401 can be configured to transform the input impedance at the driver stage 403 to a termination impedance of 50 ohms at node 402. The input matching network 401 includes a first transformer 404 that receives an input signal at the node 402. The signal at node 402 can come from, e.g., transmitter modulation circuitry, such as modulation circuitry 214 from transmitter 210. First transformer 404 splits the incoming signal received at node 402 and provides the resulting signals to the driver stage 403, which is configured to amplify the received signals. The driver stage 403 includes two arms 411, 413, in which the signal on the first arm 411 is 180 degrees out of phase with the signal on the second arm 413. Each arm 411, 413 includes one or more corresponding driver amplifiers to amplify the signal on the respective arm. For instance, as shown in FIG. 4A, a first driver amplifier 450 is included in first arm 411, whereas a second driver amplifier 452 is included in second arm 413.

Signals output from the driver stage 403 are provided to the inter-stage matching network 405, which includes a first matching circuit 454 and a second matching circuit 456. For instance, as shown in FIG. 4A, each driver amplifier 450, 452 is tied to matching circuit 454, 456, respectively. The inter-stage matching network 405 is configured to transform the impedance seen at its output (i.e., the input to stage 407) to a target impedance seen at its input (i.e., the output of the driver stage 403). Accordingly, for the example circuit shown in FIG. 4A, each matching circuit 454, 456 transforms the impedance seen at its respective output into a desired load impedance at its respective input (e.g., at the input of the IS matching circuit 405). As an example implementation, the impedance at the output of the first IS matching circuit 454 is about less than 1 ohms, and the desired target impedance at the input of the first matching circuit 454 is between about 30 ohms and 100 ohms, e.g., about 50 ohms. Similar impedance values are applicable to the second matching circuit 456. The actual desired impedance value at the input of the matching circuits 454, 456 may depend on predefined design parameters for the end product in which the RF front end circuitry is used. The IS impedance transformation ratio, which corresponds to the impedance ratio of the impedance seen at the input to the output stage 407 to the impedance seen at the input of the IS matching network 405 (e.g., within each of arms 411, 413) can be in the range of about 10 to about 100.

The matching circuits 454, 456 can be implemented using LC matching circuits having high Q. For instance, the matching circuits 454, 456 can be designed to take advantage of high Q wirebond or onchip-coil for inductance. The capacitance and/or inductance values of the matching network can be readily tuned to adjust the impedance transformation achieved by the matching network.

Signals from the output stage 407 (e.g., the output of each of push-pull amplifiers 406, 408) are combined at the output matching network 409 to provide an output signal that is sent to, e.g., antenna 412. The output matching network 409 includes a transformer 410 and is configured to transform an impedance at the antenna 412 to a target impedance required at the output of the output stage 407. The impedance seen at antenna 412 can be, e.g., 50 ohms.

FIG. 4B is a more detailed example of the circuitry 400 shown in FIG. 4A. As shown in FIG. 4B, each of the push-pull amplifiers 406, 408 of the output stage 407 can be implemented using a corresponding transistor array 414 (transistor array Q3 for amplifier 406 and transistor array Q4 for amplifier 408). Similarly, each of the driver amplifiers 450, 452 of the driver stage 403 can be implemented using a corresponding transistor 460 (e.g., transistor array Q1 for amplifier 450 and transistor array Q2 for amplifier 452). While the transistors 414 and 460 are depicted as bipolar junction transistors, other transistors, such as MOSFETs may be used instead, with appropriate modification of the circuit design to accommodate the different operation of MOSFETs compared to bipolar junction transistors.

In addition to transistor array 460, each of the driver amplifiers 450, 452 can include one or more corresponding capacitors 462 (capacitor C1 for amplifier 450 and capacitor C2 for amplifier 452) tied to an input of the transistor array, and one or more corresponding resistors 464 (e.g., resistor R1 for amplifier 450 and resistor R2 for amplifier 452) tied to the input of the transistor. Capacitors 462 work together with resistors 318 to provide ballasting for a large output stage device array as well as to provide partial impedance transformation.

As explained herein, the matching circuits 454, 456 can be implemented using LC circuits. A particular example matching circuit is shown in FIG. 4B, though other matching circuit designs are also possible. Each of the first and second matching circuits 454, 456 (identified within the dashed line boxes) includes a corresponding first inductor 470 (inductor L1 for circuit 454 and inductor L2 for circuit 456), a corresponding first capacitor 472 (capacitor C3 for circuit 454 and capacitor C4 for circuit 456), a corresponding second inductor 474 (inductor L3 for circuit 454 and inductor L4 for circuit 456), and a corresponding second capacitor 476 (capacitor C5 for circuit 454 and capacitor C6 for circuit 456). The combination of L1, C3, L3, and C5 serve as the first matching circuit 454. The combination of L2, C4, L4, and C6 serve as the second matching circuit 456. Each inductor 470 is coupled at a first end to the output of a driver amplifier in its respective arm. The other ends of the inductors 470 are tied to a shared node, which in turn is tied to a supply voltage 480. Each first capacitor 472 is coupled at a first end to the output of the driver amplifier in its respective arm. Each first capacitor 472 is coupled at a second end to both the second inductor 474 and to the second capacitor 476. Each second capacitor 476, in turn, is coupled to a corresponding input of the transistor 414 that forms part of a push-pull amplifier, whereas the second inductors 474 are tied to ground. In some implementations, the capacitors 476 constitute part of the push-pull amplifiers. For instance, capacitor C5, together with resistor 418 corresponding to R3 and transistor 414 corresponding to Q3 constitute push-pull amplifier 406, whereas capacitor C6 together with resistor 418 corresponding to R4 and transistor 414 corresponding to Q4 constitute push-pull amplifier 408. Thus, although capacitors 476 are depicted herein as being part of the IS matching network 405, capacitors may alternatively be described as being part of the output stage 407. The leads of the second transformer 410 contribute a lead inductance 420 to the circuit 400. Although a particular configuration of inductors and capacitors is shown in FIG. 4B as forming the matching circuits, other designs that incorporate different arrangements and numbers of inductors and capacitors can be used instead.

In certain implementations, the matching circuits 454, 456 are tunable. That is, the capacitance and inductance values can be modified, adjusted, or varied, e.g., in the lab, after the matching circuit components are added to the circuit board. The tunability of the matching circuits 454, 456, allows circuit designers a simplified approach to adjust driver stage loading and improve amplifier performance. By incorporating the tunable matching circuit directly into the IS matching stage 405, designers can directly tune the circuit design and reduce the number of iterative and cumbersome process of circuit design, fabrication, and testing. Once the desired performance of the RF front end circuitry is identified following the tuning process, the particular component values of the matching network can be set and incorporated into the final circuit design.

The inductors 470, 474 of the matching circuits 454, 456, as well as the leads 420 of the secondary transformer 420, can include simple wires that are bonded to the circuit board containing the RF front end circuitry. For instance, the inductor 474 can be a wire that is wire bonded at one end to a RF ground plane or ground trace on the printed circuit board, and bonded at another end to a signal trace that is coupled to, e.g., capacitors 472 and 476. Inductor 470 can be a wire that is bonded at one end to a voltage source and at another end to the output of transistor 460. When the inductors 470, 474, 420 are wires, tuning of the inductors 470, 474, 420 can include modifying the shape and/or position of the wires on the board. For instance, the wires can be bent, pushed up, pushed down, or pushed to the side, while maintaining contact to the traces on the circuit board, to alter the inductance that is exhibited by the wires. Alternatively, or in addition, the length of the wires can be modified. Such alteration of the shape and/or height of the wire bonds can be performed using, e.g., a wire bonding machine Laser trimming can also be used to adjust the inductance value of the inductors 470, 474, 420 when the inductors are implemented, e.g., as on-chip printed coils. As an example, the range of values over which the inductors 470, 474, 420 may be varied includes between about 0.8 nH to about 1.5 nH, depending on operating frequencies and loading requirements of the circuit design, where the accuracy of the inductance value is subject to the measurement equipment used. Other ranges are also possible.

In some implementations, the capacitors 472, 476 can be varied or laser trimmed over a set range of possible values. As an example, the range of values over which the capacitors 472, 476 can be varied includes between about 0.5 pF to about 3.5 pF depending on operating frequencies and loading requirement of the circuit design, where the accuracy of the capacitance value is subject to the measurement equipment used. Other ranges are also possible. Varying the values of the inductors 470, 474, and the capacitors 472, 476 can allow micro-tuning of the load presented to the output of the driver transistor Q1 and Q2. In some implementations, the capacitors 472, 476 can include a laser trimmable capacitor array, which are built up as multilayer plate capacitors, where vaporizing the top connecting layer with a laser decreases the capacitance as needed in the lab.

Once a desired driver stage Q1 and Q2 output load is achieved after tuning the inductor(s) and capacitor(s) in the matching circuits 454, 456, a final design of the RF front end circuitry can be completed based on the inductance and capacitor values of the IS matching network 405. The final design using defined capacitance and inductance values obtained from tuning the matching network then can be used in mass fabrication of the RF front end circuitry. For example, in the case of a wire adjusted to a particular shape and height for a particular inductance value, the wire used for mass production can be selected to have the same shape and height. In another example, in the case of an on-chip capacitor, such as a laser-trimmable capacitor, once the desired capacitance is determined, a capacitor having that capacitance value is selected for mass production.

The process for tuning a load of an RF amplifier circuit as described above can be set forth as follows: an adjustable matching circuit, such as circuit 454 or circuit 456, is provided between a first driver amplifier circuit of the driver stage 403 and a push-pull amplifier circuit of the output stage407, in which the adjustable matching circuit includes at least one adjustable inductor and at least one adjustable capacitor. An impedance at the output of the first driver circuit optionally can be obtained by measuring the impedance value at the first driver circuit output. Then the matching circuit is adjusted through, e.g., modifying the variable inductors and capacitors of the matching circuit, to obtain a predefined or optimized impedance at the output of the first transistor in order to optimize the amplifier's overall performance. The matching circuit can include, e.g., a first adjustable inductor and a second adjustable inductor. The inductance of the adjustable inductors can be varied between about 0.8 nH and about 1.5 nH depending on operating frequencies and loading requirement of the circuit design. The matching network can include, e.g., a first adjustable capacitor and a second adjustable capacitor. The capacitance of the adjustable capacitors can be varied between about 0.5 pF and about 3.5 pF depending on operating frequencies and loading requirement as well.

While this specification contains many specific implementation details, these should not be construed as limitations on the scope of any invention or on the scope of what may be claimed, but rather as descriptions of features that may be specific to particular embodiments of particular inventions Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system modules and components in the embodiments described above should not be understood as requiring such separation in all embodiments, and it should be understood that the described program components and systems can generally be integrated together in a single software product or packaged into multiple software products.

In addition, techniques, systems, subsystems, and methods described and illustrated in the various embodiments as discrete or separate may be combined or integrated with other systems, modules, techniques, or methods without departing from the scope of the present disclosure. Other items shown or discussed as coupled or directly coupled or communicating with each other may be indirectly coupled or communicating through some interface, device, or intermediate component whether electrically, mechanically, or otherwise. Other examples of changes, substitutions, and alterations are ascertainable by one skilled in the art and could be made without departing from the spirit and scope disclosed herein.

For purposes of this document, a connection may be a direct connection or an indirect connection (e.g., via one or more other parts). In some cases, when an element is referred to as being connected or coupled to another element, the element may be directly connected to the other element or indirectly connected to the other element via intervening elements. When an element is referred to as being directly connected to another element, then there are no intervening elements between the element and the other element. Two devices are “in communication” if they are directly or indirectly connected so that they can communicate electronic signals between them.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results.

What is claimed is:

1. A radio-frequency (RF) amplifier circuit, the RF amplifier circuit comprising:
a first matching circuit;
a driver stage circuit, wherein the first matching circuit is coupled to the driver stage circuit, and wherein the first matching circuit is configured to transform an input impedance of the driver stage circuit into a first impedance at an input to the first matching circuit;
an inter-stage matching circuit coupled to the driver stage circuit;
an output stage circuit coupled to the inter-stage matching circuit, wherein the inter-stage matching circuit is configured to transform an input impedance of the output stage circuit into a second impedance at an output of the driver stage circuit; and
a second matching circuit coupled to the output stage circuit, wherein the second matching circuit is configured to transform an impedance at an output of the second matching circuit into a third impedance at the output of the output stage circuit.

2. The RF amplifier circuit of claim 1, wherein the first matching circuit comprises a first transformer, wherein the first transformer is arranged to split an input signal to the first transformer into a first transformed signal and a second transformed signal that is out of phase with the first transformed signal.

3. The RF amplifier circuit of claim 2, wherein the driver stage circuit comprises a first driver stage amplifier and a second driver stage amplifier, wherein the first driver stage amplifier is arranged to receive the first transformed signal and the second driver stage amplifier is arranged to receive the second transformed signal.

4. The RF amplifier circuit of claim 3, wherein the inter-stage matching circuit comprises:
a first matching circuit coupled to an output of the first driver stage amplifier; and
a second matching circuit coupled to an output of the second driver stage amplifier.

5. The RF amplifier circuit of claim 4, wherein the first matching circuit comprises a first inductor-capacitor (LC) matching circuit, and wherein the second matching circuit comprises a second LC matching circuit.

6. The RF amplifier circuit of claim 5, wherein the first LC matching circuit comprises a first capacitor coupled to an output of the first driver stage amplifier, and the second LC matching circuit comprises a second capacitor coupled to an output of the second driver stage amplifier.

7. The RF amplifier circuit of claim 6, wherein the first LC matching circuit comprises a first inductor coupled between the first capacitor and ground, and wherein the second LC matching circuit comprises a second inductor coupled between the second capacitor and ground.

8. The RF amplifier circuit of claim 7, wherein the first LC matching circuit comprises a third inductor coupled between the first capacitor and a voltage source, and wherein the second LC matching circuit comprises a fourth inductor coupled between the second capacitor and the voltage source.

9. The RF amplifier circuit of claim 8, wherein the first LC matching circuit comprises a third capacitor coupled to the first capacitor and to the first inductor, and wherein the second LC matching circuit comprises a fourth capacitor coupled to the second capacitor and to the second inductor.

10. The RF amplifier circuit of claim 7, wherein each of the first inductor and the second inductor is an adjustable inductor, and wherein each of the first capacitor and the second capacitor is an adjustable capacitor.

11. The RF amplifier circuit of claim 5, wherein an impedance at the output of the first driver stage amplifier and at an input to the first LC matching circuit is between about 10 ohms and about 150 ohms, and wherein an impedance at the output of the second driver stage amplifier and at an input to the second LC matching circuit is between about 10 ohms and about 150 ohms.

12. The RF amplifier circuit of claim 11, wherein an impedance at an output of the first LC matching circuit is between about 0.1 ohms and about 1 ohms, and wherein an impedance at an output of the second LC matching circuit is between about 0.1 ohms and about 1 ohms.

13. The RF amplifier circuit of claim 1, wherein the impedance at the output of the second matching circuit is 50 ohms.

14. A radio-frequency (RF)-circuit comprising:
a processor;
modulation circuitry coupled to an output of the processor;
a push-pull amplifier circuit coupled to an output of the modulation circuitry; and
an antenna,
wherein the push-pull amplifier circuit comprises:
a first matching circuit;
a driver stage circuit, wherein the first matching circuit is coupled to the driver stage circuit, and wherein the first matching circuit is configured to transform an input impedance of the driver stage circuit into a first impedance at an input to the first matching circuit;
an inter-stage matching circuit coupled to the driver stage circuit;
an output stage circuit coupled to the inter-stage matching circuit, wherein the inter-stage matching circuit is configured to transform an input impedance of the output stage circuit into a second impedance at an output of the driver stage circuit; and
and a second matching circuit coupled to the output stage circuit, wherein the second matching circuit is configured to transform an impedance at an output of the second matching circuit into a third impedance at the output of the output stage circuit.

15. The RF circuit of claim 14, wherein the first matching circuit comprises a first transformer, wherein the first transformer is arranged to split an input signal to the first transformer into a first transformed signal and a second transformed signal that is out of phase with the first transformed signal.

16. The RF circuit of claim 15, wherein the driver stage circuit comprises a first driver stage amplifier and a second driver stage amplifier, wherein the first driver stage amplifier is arranged to receive the first transformed signal and the second driver stage amplifier is arranged to receive the second transformed signal.

17. The RF circuit of claim 16, wherein the inter-stage matching circuit comprises:
a first matching circuit coupled to an output of the first driver stage amplifier; and
a second matching circuit coupled to an output of the second driver stage amplifier.

18. The RF circuit of claim 17, wherein the first matching circuit comprises a first inductor-capacitor (LC) matching circuit, and wherein the second matching circuit comprises a second LC matching circuit.

19. A method of tuning an impedance of a radio-frequency (RF) push-pull amplifier circuit comprising a first matching circuit, a driver stage circuit coupled to an output of the first matching circuit, an inter-stage matching circuit coupled to an output of the driver circuit, an output stage circuit coupled to an output of the inter-stage matching circuit, and a second matching circuit coupled to an output of output stage circuit, the method comprising:
obtaining an impedance at the input of the output stage circuit;
adjusting an impedance matching of the inter-stage matching circuit so as to obtain a predefined impedance at the output of driver stage circuit.

20. The method of claim 19, wherein adjusting the impedance matching of the inter-stage matching circuit comprises:
adjusting an inductance of a first adjustable inductor of the inter-stage matching circuit; and
adjusting a capacitance of a first adjustable capacitor of the inter-stage matching circuit.
